(19) United States
(12) Patent Application Publication
(10) Pub. No.: US 2014/0346617 A1
(43) Pub. Date: Nov. 27, 2014

(54) SEMICONDUCTOR DEVICE AND METHOD FOR FABRICATING THE SAME

(71) Applicant: SAMSUNG ELECTRONICS CO., LTD., Suwon-si (KR)

(72) Inventors: Jong-Pil KIM, Hwaseong-si (KR); Yun-Young YEOH, Seoul (KR)

(73) Assignee: SAMSUNG ELECTRONICS CO., LTD., Suwon-si (KR)

(21) Appl. No.: 14/228,806

(22) Filed: Mar. 28, 2014

(30) Foreign Application Priority Data
May 27, 2013 (KR) 10-2013-0059866

(51) Int. Cl. H01L 29/78; H01L 29/66

(52) U.S. Cl. CPC H01L 29/785; H01L 29/66795
USPC 257/412

(57) ABSTRACT

A semiconductor device includes an interlayer insulating film on a substrate, the interlayer insulating film including first and second trenches, a gate insulating film in the first and second trenches, a first conductivity type work function control film on the gate insulating film in the first trench, a second conductivity type work function control film on the gate insulating film in the second trench, a first gate metal on the first conductivity type work function control film, the first gate metal filling the first trench, a second gate metal on the gate insulating film in the second trench, and a carrier mobility improving film on the second conductivity type work function control film, the carrier mobility improving film filling the second trench.

### CROSS-REFERENCE TO RELATED APPLICATION

Korean Patent Application No. 10-2013-0059866, filed on May 27, 2013, in the Korean Intellectual Property Office, and entitled: “Semiconductor Device and Method for Fabricating the Same,” is incorporated by reference herein in its entirety.

### BACKGROUND

1. Field

Embodiments relate to a semiconductor device and a method of fabricating the same.

2. Description of the Related Art

Feature sizes of a metal oxide semiconductor (MOS) transistor may be reduced with an increasing degree of integration. Accordingly, the length of a gate and the length of a channel formed therebelow may decrease.

### SUMMARY

Embodiments are directed to a semiconductor device, including an interlayer insulating film on a substrate, the interlayer insulating film including first and second trenches, a gate insulating film in the first and second trenches, a first conductivity type work function control film on the gate insulating film in the first trench, a second conductivity type work function control film on the gate insulating film in the second trench, a first gate metal on the first conductivity type work function control film, the first gate metal filling the first trench, a second gate metal on the gate insulating film in the second trench, and a carrier mobility improving film on the second conductivity type work function control film, the carrier mobility improving film filling the second trench.

The second gate metal may include a third trench formed in the second trench.

A top surface of the second gate metal may be recessed.

The semiconductor device may further include fins on the substrate and under the gate insulating film.

The first conductivity type work function control film and the second conductivity type work function control film may be different from each other.

The first conductivity type work function control film may be a P type and the second conductivity type work function control film may be an N type.

In the second trench, a volume of the second gate metal may be smaller than that of the carrier mobility improving film.

The first and second gate metals may include a first material, and the carrier mobility improving film may include a second material different from the first material.

The second material may include TiN.

A lattice constant of the second material may be smaller than that of the first material.

Embodiments are also directed to a semiconductor device, including a substrate including an NMOS region, a gate insulating film on the NMOS region, an N type work function control film on the gate insulating film, a gate metal on the N type work function control film and including a first material, and a carrier mobility improving film on the gate metal and including a second material, a lattice constant of the second material being smaller than that of the first material.

The N type work function control film may include a first trench, the gate metal may be formed at a lower portion of the trench, and the carrier mobility improving film may be formed to fill the trench.

A volume of the gate metal may be smaller than that of the carrier mobility improving film in the trench.

The gate metal may include a second trench.

Embodiments are also directed to a semiconductor device, including a substrate including a first region and a second region, a P-type transistor in the first region, the P-type transistor having a first channel region and having a first gate structure disposed on the first channel region, the first gate structure including a first gate metal in a first trench that overlaps the first channel region, the first gate structure including a first material layer in the first trench under the first gate metal, the first material layer being interposed between a bottom of the first trench and the first gate metal over the first channel region, the first material layer being formed from a first material selected from the group of Mo, Pd, Ru, Pt, TiN, WN, TaN, Ir, TaC, RuN, and MoN, and an N-type transistor in the second region, the N-type transistor having a second channel region and having a second gate structure disposed on the second channel region, the second gate structure including a second gate metal in a second trench that overlaps the second channel region, the second gate structure including a titanium nitride layer in the second trench under the second gate metal, the titanium nitride layer being interposed between a bottom of the second trench and the second gate metal over the second channel region, wherein the second gate structure does not include the first material in the second trench.

The first gate metal may be tungsten or aluminum, and the second gate metal may be tungsten or aluminum.

In the second trench, the second gate metal may contact the titanium nitride layer.

The second gate structure may include a second material layer interposed between a bottom of the second trench and the titanium nitride layer over the second channel region, the second material layer being formed from a second material selected from the group of TiAl, TiAlN, TaC, TiC, and HfSi.

The P-type transistor may have a first fin extending from the substrate in the first channel region, the first gate structure being disposed along sidewalls and a top of the first fin, the first trench being at a top of the first fin, and the N-type transistor may have a second fin extending from the substrate in the second channel region, second gate structure being disposed along sidewalls and a top of the second fin, the second trench being at a top of the second fin.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view of a semiconductor device according to a first example embodiment;

FIG. 2 illustrates a cross-sectional view of a semiconductor device according to a second example embodiment;

FIG. 3 illustrates a perspective view of a semiconductor device according to a third example embodiment;

FIG. 4 illustrates a cross-sectional view taken along the line A-A of FIG. 3;

FIG. 5 illustrates a cross-sectional view taken along the line B-B of FIG. 3;

FIG. 6 illustrates a cross-sectional view of a semiconductor device according to a fourth example embodiment;

FIGS. 7 and 8 illustrate a circuit view and a layout view of a semiconductor device 5 according a fifth example embodiment;

FIG. 9 illustrates a block diagram of an electronic system including a semiconductor device according to example embodiments;

FIGS. 10 and 11 illustrate exemplary semiconductor systems to which the semiconductor device according to example embodiments may be applied;

FIGS. 12 to 15 illustrate cross-sectional views of stages in a method of fabricating the semiconductor device according to the first example embodiment;

FIG. 16 illustrates a cross-sectional view of a stage in a method of fabricating the semiconductor device according to the first example embodiment;

FIGS. 17 to 23 illustrate cross-sectional views of stages in a method of fabricating the semiconductor device according to the third example embodiment; and

FIG. 24 illustrates a cross-sectional view of a stage in a method of fabricating the semiconductor device according to the fourth example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will also be understood that when a layer is referred to as being “on” another layer or substrate, it may be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper,” and the like may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a,” “an,” and “the” and similar referents in the context of describing the embodiments (including in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It will be understood that, although the terms first, second, etc. may be used herein to describe various elements, these elements should not be limited by these terms. These terms are only used to distinguish one element from another element. Thus, for example, a first element, a first component, or a first section discussed below could be termed a second element, a second component, or a second section.

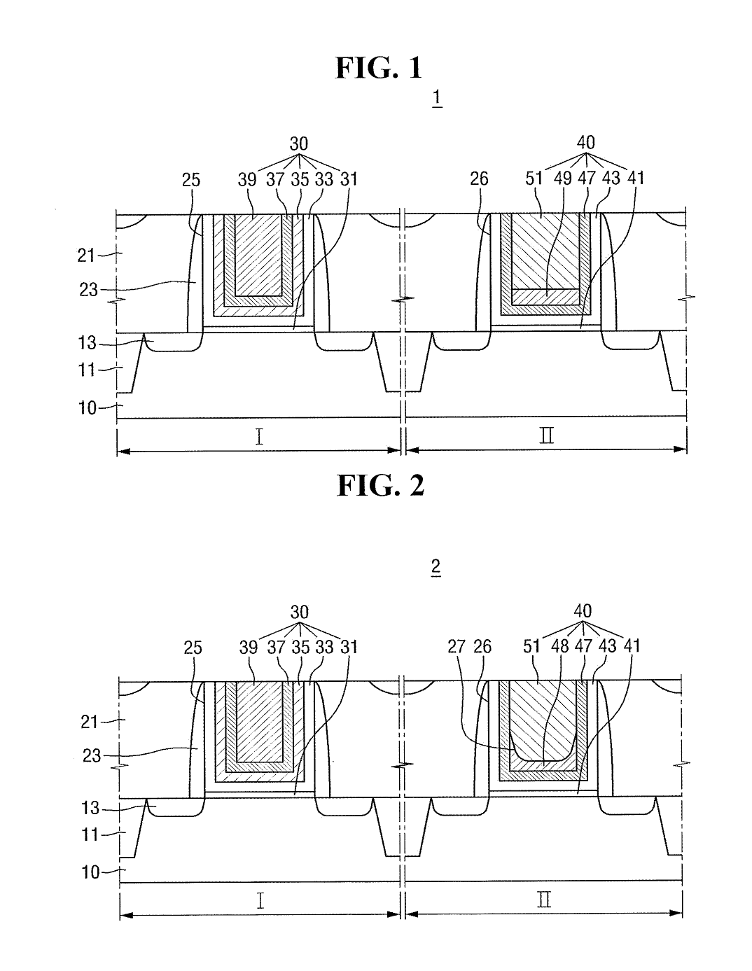

Hereinafter, a semiconductor device according to a first example embodiment will be described with reference to FIG. 1.

FIG. 1 illustrates a schematic sectional view of a semiconductor device according to a first example embodiment.

Referring to FIG. 1, the semiconductor device 1 according to the first example embodiment includes a substrate 10, an interlayer insulating film 21 including a first trench 25 and a second trench 26, and first and second gate structures 30 and 40.

An isolation film 11 such as a shallow trench isolation (STI) film may be formed in the substrate 10 to define an active region. The substrate 10 may be a rigid substrate, such as a substrate made of one or more semiconductor materials, for example, Si, Ge, SiGe, GaP, GaAs, SiC, SiGeC, InAs, or InP, a silicon-on-insulator (SOI) substrate, a quartz substrate, or a glass substrate for display, or a flexible plastic substrate made of, e.g., polyimide, polyethylene terephthalate (PET), polyethylene naphthalate (PEN), polymethyl methacrylate (PMMA), polycarbonate (PC), polyether sulfone (PES), or polyester.

According to the present example embodiment, a first region I and a second region II are defined in the substrate 10. The first and second regions I and II may be separated from each other or may be connected to each other. For example, the first region I may be a PMOS region and the second region II may be an NMOS region, etc.

The interlayer insulating film 21 may be formed on the substrate 10 and may include the first and second trenches 25 and 26. The first trench 25 may be formed on the first region I and the second trench 26 may be formed on the second region II. The interlayer insulating film 21 may be formed by stacking two or more layers of insulating films.

As shown in FIG. 1, a spacer 23 may be formed on sidewalls of the first and second trenches 25 and 26, and the substrate 10 may be disposed at the bottom surface of the first and second trenches 25 and 26. The spacer 23 may be formed of at least one of a nitride film and an oxynitride film. The spacer 23 may be formed in an L shape (not shown). In FIG. 1, the spacer 23 is formed of a single layer; in other implementations the spacer 23 may be formed of multiple layers.

A source/drain 13 may be formed in the substrate 10 at at least one side of the first and second gate structures 30 and 40.

The first gate structure 30 may be formed in the first trench 25. The second gate structure 40 may be formed in the second trench 26. The first gate structure 30 may include a first interface film 31, a first gate insulating film 33, a first conductivity type work function control film 35, and a first gate metal 39. The second gate structure 40 may include a second interface film 41, a second gate insulating film 43, a second conductivity type second work function control film 47, a second gate metal 49, and a carrier mobility improving film 51.

The first and second interface films 31 and 41 may be formed along bottom surfaces of the first and second trenches 25 and 26, respectively. The first and second interface films 31 and 41 may help improve an interface between the semiconductor substrate 10 and the first and second gate insulating films 33 and 43. The first and second interface films 31 and 41 may include a low-k material layer having a dielectric constant (k) of 9 or less, for example, a silicon oxide film (k=4) or a silicon oxynitride film (k=4 to 8 according to the concentration of oxygen or nitrogen atoms). In another implementation, the first and second interface films 31 and 41 may include silicate, or a combination of the films listed above.

If the first and second interface films 31 and 41 are silicon oxide films, they may be formed by, for example, a thermal oxidation process, etc.

The first gate insulating film 33 may be conformally formed along the sidewall and bottom surface of the first trench 25 on the first interface film 31. The second gate insulating film 43 may be conformally formed along the sidewall and bottom surface of the second trench 26 on the second interface film 41.

The first and second gate insulating films 33 and 43 may include a high-k dielectric material having a higher dielectric constant than a silicon oxide film. For example, the first and second gate insulating films 33 and 43 may include a material selected from the group of HfSiON, HfO₂, ZrO₂, Ta₂O₅, TiO₂, SrTiO₅, and (Ba,Sr)TiO₅. The first and second gate insulating films 33 and 43 may be formed to appropriate thicknesses according to the kind of a target device to be formed.

The first conductivity type work function control film 35 may be formed on the first gate insulating film 33. For example, the first conductivity type work function control film 35 may be conformally formed along the sidewall and bottom surface of the first trench 25 on the first gate insulating film 33 in the first trench 25, like the first gate insulating film 33. According to the present example embodiment, the first conductivity type work function control film 35 is not formed in the second trench 26 of the second region II. The first conductivity type work function control film 35 may control a work function of the first gate structure 30 and may determine whether a transistor operates as an N type transistor or a P type transistor.

The second conductivity type second work function control film 47 may be formed on the second gate insulating film 43 in the second trench 26, and may be conformally formed along the sidewall and bottom surface of the second trench 26. The second conductivity type second work function control film 47 may control a work function of the second gate structure 40.

In an example embodiment, a second conductivity type first work function control film 37 may be formed on the first conductivity type work function control film 35 in the first trench 25. According to the present example embodiment, although the second conductivity type first work function control film 37 is formed on the first conductivity type work function control film 35, only the first conductivity type work function control film 35 affects the work function of the first gate structure 30, and the second conductivity type first work function control film 37 is formed on the first conductivity type work function control film 35 so as not to affect the word function of the first gate structure 30.

According to the present example embodiment, the first conductivity type work function control film 35 is different from the second conductivity type work function control films 37 and 47. For example, the first conductivity type of the first conductivity type work function control film 35 may be a P type, and the second conductivity type of the second conductivity type work function control films 37 and 47 may be an N type. In an example embodiment, a P type transistor may be formed in the first region I and an N type transistor may be formed in the second region II.

If the first conductivity type is the P type, the first conductivity type work function control film 35 may include, for example, a material selected from the group of Mo, Pd, Ru, Pt, TiN, WN, TaN, Ir, TaC, RuN, and MoN. If the second conductivity type is the N type, the second conductivity type work function control films 37 and 47 may include, for example, a material selected from the group of TiAl, TiAlN, TaC, TiC, and HfSi.

According to the present example embodiment, the second conductivity type first work function control film 37 is formed on the first conductivity type work function control film 35. In another example embodiment, only the first conductivity type work function control film 35 may be formed in the first trench 25.

According to the present example embodiment, the first gate metal 39 is formed on the second conductivity type first work function control film 37. The first gate metal 39 is formed on the second conductivity type first work function control film 37 to fill the first trench 25. The first gate metal 39 may include a first material and the first material may include, for example, at least one of Al and W.

The second gate metal 49 is formed on the second conductivity type second work function control film 47. The second gate metal 49 may include the first material included in the first gate metal 39 and may be formed in the second trench 26.

According to the present example embodiment, the carrier mobility improving film 51 is formed on the second gate metal 49 to fill the second trench 26, and is not formed on the first gate metal 39. Thus, the carrier mobility improving film 51 is formed in the second trench 26 and not the first trench 25.

The carrier mobility improving film 51 may include a second material. The second material may be different from the first material included in the first and second gate metals 39 and 49. A lattice constant of the second material may be smaller than that of the first material, and a compressive stress applied to a channel region of the substrate 10 by the carrier mobility improving film 51 may be smaller than that applied to the channel region of the substrate 10 by the first and second gate metals 39 and 49. The second material may include, for example, TiN, etc. The second material may be a material having a smaller compressive stress than the first material.

According to the present example embodiment, the first material included in the first and second gate metals 39 and 49 has a relatively large lattice constant. Thus, the first and second gate metals 39 and 49 may apply a pressure to the channel region. The pressure may improve performance of a P type transistor in a PMOS region in which the current flows by holes. However, in an NMOS region in which the current flows through a carrier, the pressure may deteriorate performance of an N type transistor. For example, as the size of a transistor is reduced, the length of a channel region may be reduced, deteriorating the performance of the N type transistor. Therefore, according to the present example embodiment, a portion of the second gate metal 49 is left in the second trench 26 and the other portion of the second trench 26 is filled with the carrier mobility improving film 51, which may reduce the compressive stress applied to the channel region by the second gate structure 40 and improve the performance of the N type transistor. If the carrier mobility improving film 51 applies a tensile stress to the channel region, the performance of the N type transistor may be further improved.

In the second trench 26, a volume of the second gate metal 49 may be smaller than that of the carrier mobility improving film 51. As the volume of the carrier mobility improving film 51 occupying the second trench 26 is increased, the volume of the second gate metal 49 occupying the second trench 26 is reduced and the compressive stress applied to the channel region by the second gate metal 49 is reduced. Therefore, the performance of the N type transistor may be improved as the volume of the carrier mobility improving film 51 is increased.

If the second gate metal 49 is not entirely removed and a portion of the second gate metal 49 is left without being completely removed, the resistance characteristic of the second gate structure 40 may be improved, compared to a case where the second trench 26 is entirely filled with the carrier mobility improving film 51.

Next, a semiconductor device 2 according to a second example embodiment will be described with reference to FIG. 2. Repeated descriptions of the semiconductor devices 1 and 2 according to the first and second example embodiments may be omitted to avoid repetition and focus the following description on differences therebetween.

FIG. 2 illustrates a cross-sectional view of a semiconductor device 2 according to a second example embodiment.

Referring to FIG. 2, the semiconductor device 2 according to the second example embodiment is different from the semiconductor device 1 according to the first embodiment in view of a configuration of a second gate metal 48. As shown in FIG. 2, the second gate metal 48 includes a third trench 27 formed in the second trench 26. The third trench 27 may be formed by a fabricating process of the semiconductor device 2, described below. A top surface of the second gate metal 48 may be recessed. Thus, on the second conductivity type second work function control film 47, the second gate metal 48 is not only on a bottom surface of the second trench 26 but may also be on part of sidewalls of the second conductivity type second work function control film 47. The carrier mobility improving film 51 may fill the third trench 27 formed by the second gate metal 48 and the other portion of the second trench 26 that is not filled by the second gate metal 48. According to the present example embodiment, the second gate metal 48 fills only a portion of the second trench 26 and the carrier mobility improving film 51 applies a smaller compressive stress to a channel region than the second gate metal 48. Thus, the semiconductor device 2 according to the second example embodiment may also improve performance of an N type transistor.

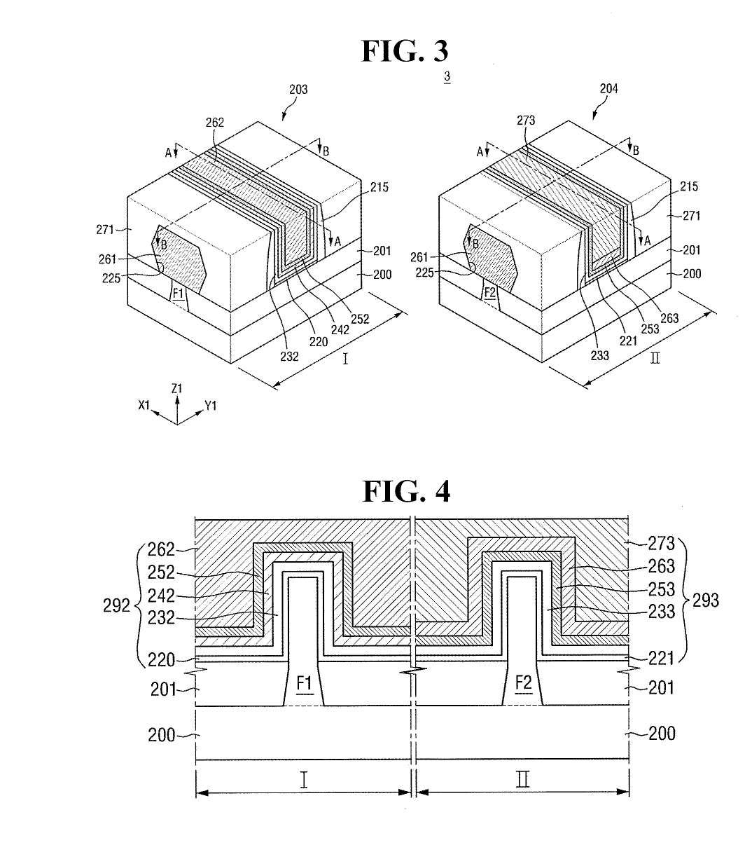

A semiconductor device 3 according to a third example embodiment will now be described with reference to FIGS. 3 to 5.

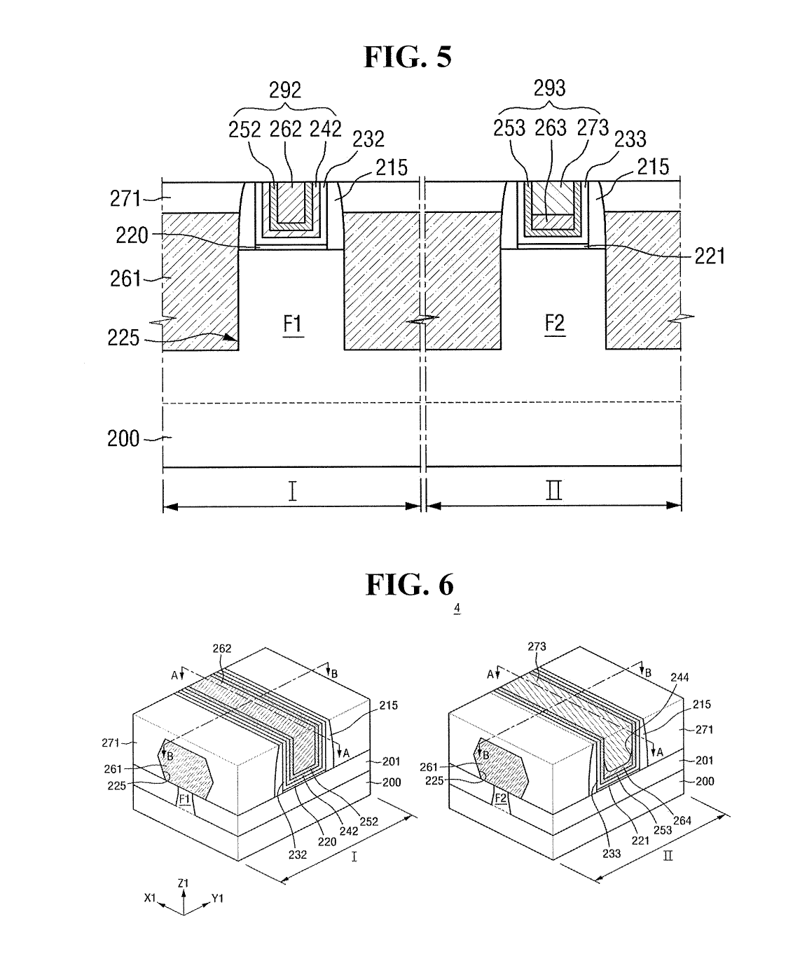

FIG. 3 illustrates a perspective view of a semiconductor device 3 according to a third example embodiment, FIG. 4 illustrates a cross-sectional view taken along the line A-A of FIG. 3, and FIG. 5 illustrates a cross-sectional view taken along the line B-B of FIG. 3.

Referring to FIGS. 3 to 5, the semiconductor device 3 according to the third example embodiment may include first and second fin type transistors 203 and 204.

The first fin type transistor 203 may be formed in a first region I and the second fin type transistor 204 may be formed in a second region II. The first region I and the second region II may be spaced apart from each other or may be connected to each other. For example, the first region I may be a PMOS region and the second region II may be an NMOS region, etc.

The first and second fin type transistors 203 and 204 may include first and second fins F1 and F2, first and second gate electrodes 292 and 293, a recess 225, and a source/drain 261.

The first and second fins F1 and F2 may extend lengthwise in a second direction Y1. The first and second fins F1 and F2 may be part of a substrate 200 and may include an epitaxial layer grown from the substrate 200. An isolation region 201 may cover side surfaces of the first and second fins F1 and F2.

A first gate electrode 292 may be formed on the first fin F1. A second gate electrode 293 may be foamed on the second fin F2. The first and second gate electrodes 292 and 293 may be formed on the first and second fins F1 and F2 to cross the first and second fins F1 and F2. The first and second gate electrodes 292 and 293 may extend in a first direction X1.

In FIG. 3, for the sake of convenient explanation, the first and second fins F1 and F2 extend lengthwise in a second direction Y1 to be parallel to each other. In another implementation, the first fin F1 may extend lengthwise in the second direction Y1 and the second fin F2 may extend lengthwise in the first direction X1.

Likewise, in the present example embodiment, the first gate electrode 292 and the second gate electrode 293 extend lengthwise in the first direction X1. In another implementation, the first gate electrode 292 may extend lengthwise in the first direction X1 and the second gate electrode 293 may extend lengthwise in the second direction Y1.

The first gate electrode 292 may include a first interface film 220, a first gate insulating film 232, a first work function control film 252, and a first gate metal 262, which are sequentially formed on the first fin F1. The second gate electrode 293 may include a second interface film 221, a second gate insulating film 233, a second work function control film 253, a second gate metal 263, and a carrier mobility improving film 273, which are sequentially formed on the second fin F2.

According to the present example embodiment, the first and second interface films 220 and 221 are formed on top surfaces of the first and second fins F1 and F2, respectively, and may help prevent charges from being trapped between the first and second fins F1 and F2 and the first and second gate insulating films 232 and 233 due to a poor interface.

The first and second gate insulating films 232 and 233 are formed on the first and second interface film 220 and 221, respectively. As shown in FIG. 4, the first and second gate insulating films 232 and 233 may be formed on top surfaces and upper portions of side surfaces of the first and second fins F1 and F2. The first and second gate insulating films 232 and 233 may include a high-k dielectric material having a higher dielectric constant than a silicon oxide film. For example, the first and second gate insulating films 232 and 233 may include one or more of HfO₂, ZrO₂, or Ta₂O₅.

The first and second work function control films 242 and 253 are formed on the first and second gate insulating films 232 and 233, respectively. As shown in FIG. 4, the first and second work function control films 242 and 253 may be conformally formed on the top surfaces and upper portions of side surfaces of the first and second fins F1 and F2. The first work function control film 252 and the second work function control film 253 may be different from each other. For example, the first work function control film 252 may be a P type work function control film pattern and the second work function control film 253 may be an N type work function control film pattern.

A second work function control film 252 may be formed on the first work function control film 252. According to the present example embodiment, although the second work function control film 252 is formed on the first work function control film 252, the second work function control film 252 does not affect a work function of the first gate electrode 292.

The first and second gate metals 262 and 263 may be formed on the first and second work function control films 242 and 253, respectively. The first gate metal 262 may be formed on the first work function control film 242 so as to fill the other portions of the first gate electrode 292. The second gate metal 263 may be formed on the second work function control film 253 and may not entirely fill the other portions of the second gate electrode 293 but may partially fill the other portions of the second gate electrode 293. The other portions of the second gate electrode 293 may be filled with the carrier mobility improving film 273. According to the present example embodiment, the carrier mobility improving film 273 is formed on the second gate metal 263.

The first and second gate metals 262 and 263 may include a first material, and the carrier mobility improving film 273 may include a second material different from the first material. The first material may include, for example, W or Al. According to the present example embodiment, a lattice constant of the second material is smaller than that of the first material. Thus, the second material may be a material capable of applying a smaller compressive stress to a channel region than the first material. The second material may be, for example, TiN, etc. According to the present example embodiment, the carrier mobility improving film 273 applies a smaller compressive stress to the channel region than the second gate metal 263. Thus, carrier mobility in the channel region of the NMOS region may be improved.

The first and second gate electrodes 292 and 293 may be formed by, for example, a replacement process, etc.

The recess 225 may be formed in the first and second fins F1 and F2 of both sides of the first and second gate electrodes 292 and 293. As shown in FIG. 3, a width of the recess 225 may be greater than widths of the fins F1 and F2.

According to the present example embodiment, the source/drain 261 is formed in the recess 225. The source/drain 261 may be an elevated source/drain. Thus, a top surface of the source/drain 261 may be higher than a bottom surface of the interlayer insulating film 271. In addition, the source/drain 261 and the gate electrode 292 may be insulated from each other by the spacer 215.

If the first region I is a PMOS region, the source/drain 261 of the first region I may include a compressive stress material. For example, the compressive stress material may have a larger lattice constant than Si, and may be for example, SiGe. The compressive stress material may apply a compressive stress to the first fin F1, which may improve carrier mobility of the channel region.

If the second region II is an NMOS region, the source/drain 261 of the second region II may include the same material as the substrate 200 or a tensile stress material. For example, when the substrate 200 includes Si, the source/drain 261 of the second region II may include Si or a material having a smaller lattice constant than Si (e.g., SiC).

The spacer 215 may be formed of at least one of a nitride film and an oxynitride film.

The substrate 200 may include one or more semiconductor materials selected from the group of, for example, Si, Ge, SiGe, GaP, GaAs, SiC, SiGeC, InAs, and InP. In an implementation, the substrate 200 may be a silicon-on-insulator (SOI) substrate.

A semiconductor device 4 according to a fourth example embodiment will now be described with reference to FIG. 6. Repeated descriptions of the semiconductor devices 3 and 4 according to the third and fourth example embodiments may be omitted to avoid repetition and focus the following description on differences therebetween.

FIG. 6 illustrates a cross-sectional view of a semiconductor device according to a fourth example embodiment.

Referring to FIG. 6, the semiconductor device 4 according to the fourth example embodiment is different from the semiconductor device 3 according to the third embodiment in view of a configuration of a second gate metal 264.

According to the present example embodiment, the second gate metal 264 includes a third trench 244 and a top surface of the second gate metal 264 may be recessed. Thus, on a second work function control film 253, the second gate metal 264 is not only on a bottom surface of the second trench 243 but may be on part of sidewalls of the second work function control film 253. A carrier mobility improving film 273 may fill a third trench 244 formed by the second gate metal 264 and the other portion of a second gate electrode 293 that is not filled by the second gate metal 264. When the carrier mobility improving film 273 is formed on the second gate metal 264, the second gate electrode 293 applies a smaller compressive stress to a channel region than in a case where only the second gate metal 264 is formed. Therefore, the semiconductor device 4 according to the fourth example embodiment may also improve performance of an N type transistor.

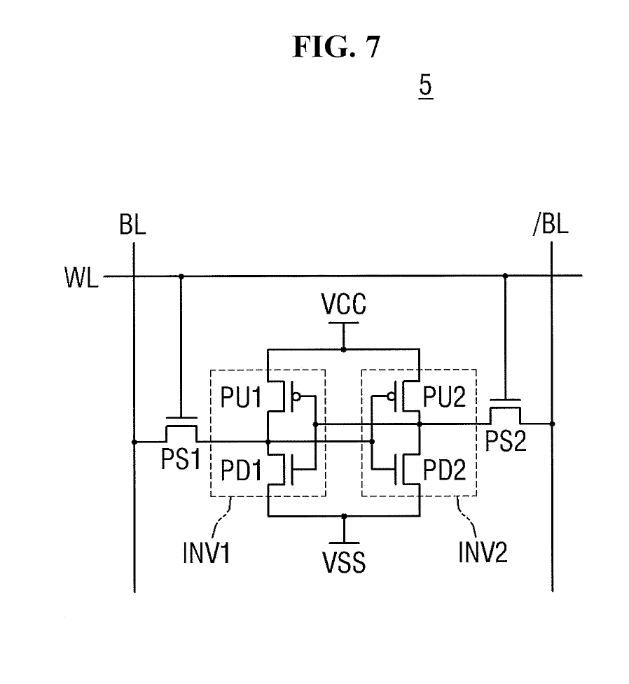

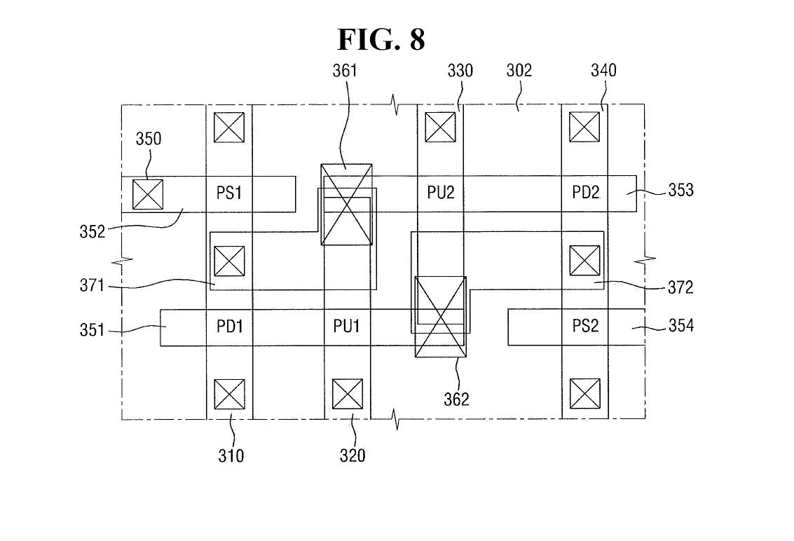

A semiconductor device 5 according a fifth example embodiment will now be described with reference to FIGS. 7 and 8.

FIGS. 7 and 8 illustrate a circuit view and a layout view, respectively, of a semiconductor device 5 according a fifth example embodiment.

Referring to FIGS. 7 and 8, the semiconductor device 5 may include a pair of inverters INV1 and INV2 connected in parallel between a power supply node Vcc and a ground node Vss, and a first pass transistor PS1 and a second pass transistor PS2 connected to output nodes of the respective inverters INV1 and INV2. The first pass transistor PS1 and the second pass transistor PS2 may be connected to a bit line BL and a complementary bit line /BL, respectively. Gates of the first pass transistor PS1 and the second pass transistor PS2 may be connected to word lines WL.

The first inverter INV1 may include a first pull-up transistor PU1 and a first pull-down transistor PD1 connected in series, and the second inverter INV2 may include a second pull-up transistor PU2 and a second pull-down transistor PD2 connected in series. The first pull-up transistor PU1 and the second pull-up transistor PU2 may be PFET transistors, and the first pull-down transistor PD 1 and the second pull-down transistor PD2 may be NFET transistors.

According to the present example embodiment, in order to allow the first inverter INV1 and the second inverter INV2 to constitute a latch circuit, an input node of the first inverter INV1 is connected to the output node of the second inverter INV2, and an input node of the second inverter INV2 is connected to the output node of the first inverter INV1.

Referring to FIGS. 7 and 8, a first active region 310, a second active region 320, a third active region 330 and a fourth active region 340, which are spaced apart from one another, are formed to extend lengthwise in a direction (for example, in an up-down direction shown in FIG. 8). The second active region 320 and the third active region 330 may extend in shorter lengths than the first active region 310 and the fourth active region 340.

In addition, the first gate electrode 351, the second gate electrode 352, the third gate electrode 353 and the fourth gate electrode 354 extend lengthwise in another direction (for example, in a left-right direction shown in FIG. 8) so as to cross the first active region 310 to the fourth active region 340. The first gate electrode 351 may completely cross the first active region 310 and the second active region 320, and may partially overlap with a terminal end of the third active region 330. The third gate electrode 353 may completely cross the fourth active region 340 and the third active region 330, and may partially overlap with a terminal end of the second active region 320. The second gate electrode 352 and the fourth gate electrode 354 are formed to cross the first active region 310 and the fourth active region 340, respectively.

According to the present example embodiment, the first pull-up transistor PU1 is defined around a region where the first gate electrode 351 and the second active region 320 cross each other, the first pull-down transistor PD1 is defined around a region where the first gate electrode 351 and the first active region 310 cross each other, and the first pass transistor PS1 is defined around a region where the second gate electrode 352 and the first active region 310 cross each other. The second pull-up transistor PU2 is defined around a region where the third gate electrode 353 and the third active region 330 cross each other, the second pull-down transistor PD2 is defined around a region where the third gate electrode 353 and the fourth active region 340 cross each other, and the second pass transistor PS2 is defined around a region where the fourth gate electrode 354 and the fourth active region 340 cross each other.

Although not shown, sources/drains may be formed at opposite sides of the regions where the first to fourth gate electrodes 351 to 354 and the first to fourth active regions 310, 320, 330 and 340 cross each other. A plurality of contacts 350 may be formed.

According to the present example embodiment, a first shared contact 361 concurrently connects the second active region 320, the third gate line 353, and a wire 371. A second shared contact 362 concurrently connects the third active region 330, the first gate line 351, and a wire 372.

For example, the first pull-up transistor PU1 and the second pull-up transistor PU2 may have the same configuration as that of one of the aforementioned P-type transistors according to example embodiments. The first pull-down transistor PD1, the first pass transistor PS1, the second pull-down transistor PD2, and the second pass transistor PS2 may have the same configuration as that of one of the aforementioned N-type transistors according to example embodiments.

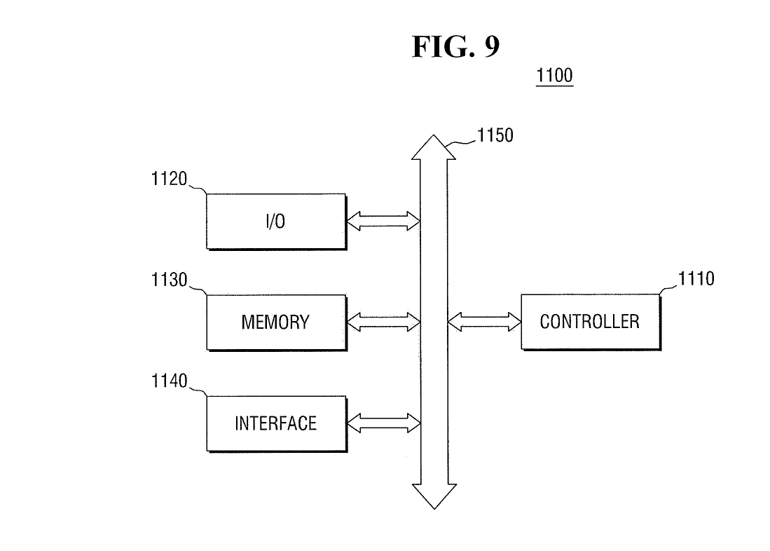

Next, an electronic system including a semiconductor device according to example embodiments will be described with reference to FIG. 9.

FIG. 9 illustrates a block diagram of an electronic system including a semiconductor device according to example embodiments.

Referring to FIG. 9, the electronic system 1100 may include a controller 1110, an input/output device (I/O) 1120, a memory device 1130, an interface 1140, and a bus 1150.

The controller 1110, the I/O 1120, the memory 1130, and/or the interface 1140 may be connected to each other through the bus 1150. The bus 1150 corresponds to a path along which data moves.

The controller 1110 may include at least one of a microprocessor, a digital signal processor, a microcontroller, and logic devices capable of performing functions similar to those of these components. The I/O 1120 may include a keypad, a keyboard, a display, and so on. The memory 430 may store data and/or commands. The interface 1140 may transmit data to a communication network or receive data from the communication network. The interface 1140 may be wired or wireless. For example, the interface 1140 may include an antenna or a wired/wireless transceiver. Although not shown, the electronic system 1100 may include an operating memory for improving the operation of the controller 1110 and may further include a high-speed DRAM and/or SRAM.

The semiconductor devices 1 to 8 according to example embodiments may be provided into the memory device 1130 or may be provided as part of the controller 1110 or the I/O 1120.

The electronic system 1100 may be applied to a personal digital assistant (PDA), a portable computer, a web tablet, a wireless phone, a mobile phone, a digital music player, a memory card, or any type of electronic device capable of transmitting and/or receiving information in a wireless environment.

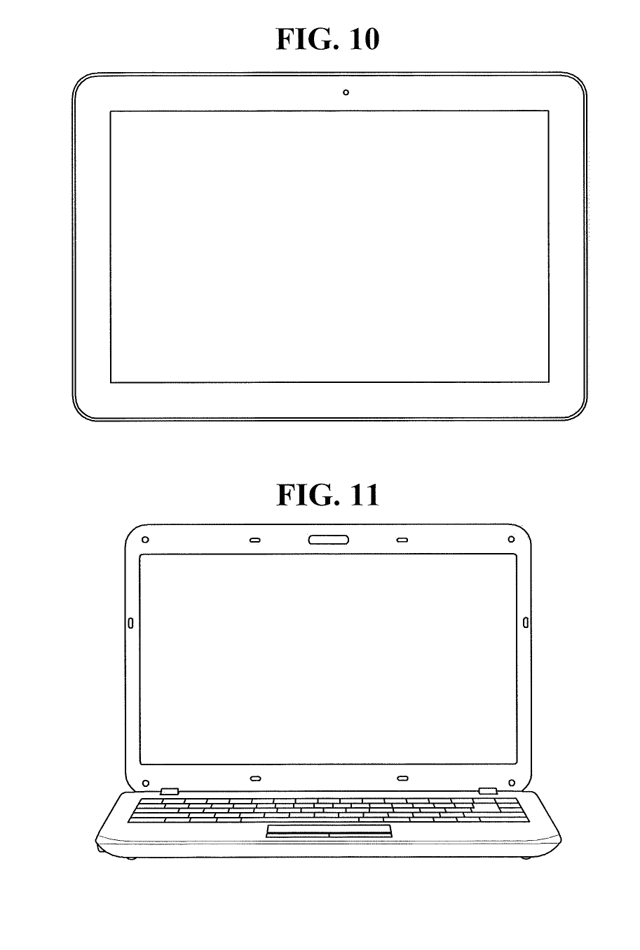

FIGS. 10 and 11 illustrate exemplary semiconductor systems to which the semiconductor device according to example embodiments may be applied. Specifically, FIG. 10 illustrates a tablet PC and FIG. 11 illustrates a notebook computer. Some of the semiconductor devices according to example embodiments may be applied to the tablet PC, a notebook computer, other integrated circuit devices, etc.

Next, a method of fabricating the semiconductor device 1 according to the first example embodiment will be described with reference to FIGS. 1 and 12 to 15. In the following descriptions, previously-described details may not be repeated.

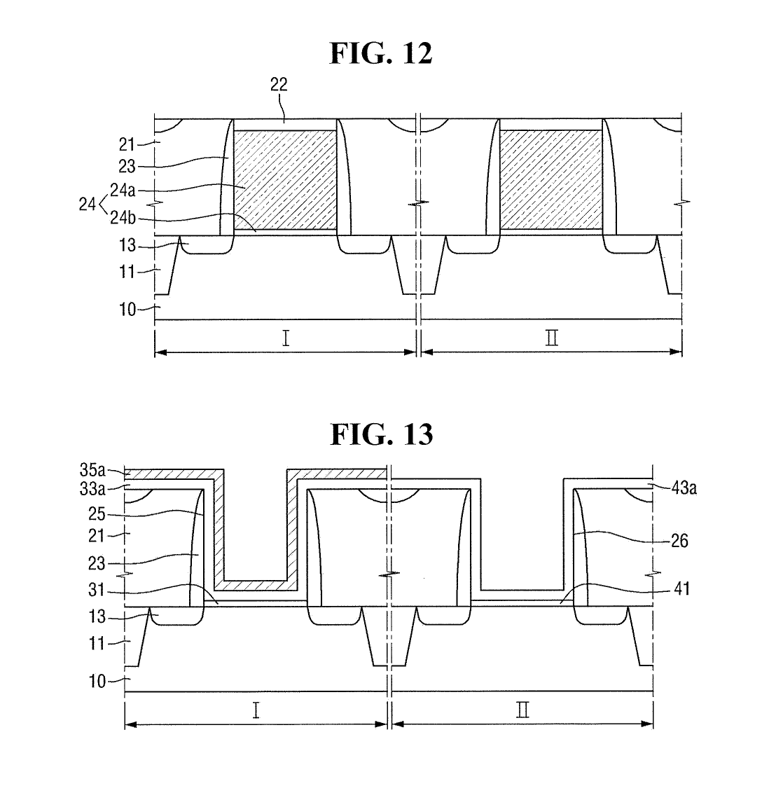

FIGS. 12 to 15 illustrate cross-sectional views of stages in a method of fabricating the semiconductor device according to the first example embodiment.

First, referring to FIG. 12, an interlayer insulating film 21 may be formed a substrate 10. The substrate 10 may include a first region I and a second region II. The first region I and the second region II may be connected to each other or may be spaced apart from each other. For example, the first region I may be a PMOS region and the second region II may be an NMOS region, etc. An isolation film 11 such as a shallow trench isolation (STI) film may be formed in the substrate 10 to define an active region.

According to the present example embodiment, a dummy gate structure 24 is disposed on the first region I and the second region II. The dummy gate structure 24 may include a dummy gate insulating film 24b and a dummy gate electrode 24a. The dummy gate insulating film 24b and the dummy gate electrode 24a are sequentially stacked on the substrate 10. A hard mask layer 22 is formed on the dummy gate electrode 24a.

The interlayer insulating film 21 is formed to cover both side surfaces of the dummy gate structure 24. A top surface of the hard mask layer 22 is exposed.

A spacer 23 is formed on the side surfaces of the dummy gate structure 24.

Referring to FIG. 13, the dummy gate structure 24 is removed to form first and second trenches 25 and 26. A top surface of the substrate 10 may be exposed in the first and second trenches 25 and 26.

Next, first and second interface films 31 and 41 and first and second gate insulating films 33a and 43a are sequentially formed in the first and second trenches 25 and 26. The first and second interface films 31 and 41 may be formed on the top surface of the substrate 10 exposed in the first and second trenches 25 and 26. The first and second gate insulating films 33a and 43a are formed on the first and second interface films 31 and 41. The first and second gate insulating films 33a and 43a may be conformally formed along sidewalls and bottom surface of the first and second trenches 25 and 26.

Next, a first conductivity type work function control film 35a is formed on the first gate insulating film 33a of the first region I. According to the present example embodiment, the first conductivity type work function control film 35a is not formed on the second region II. The first conductivity type work function control film 35a may be conformally formed along the sidewall and bottom surface of the first trench 25. The first conductivity type may be a P type, etc.

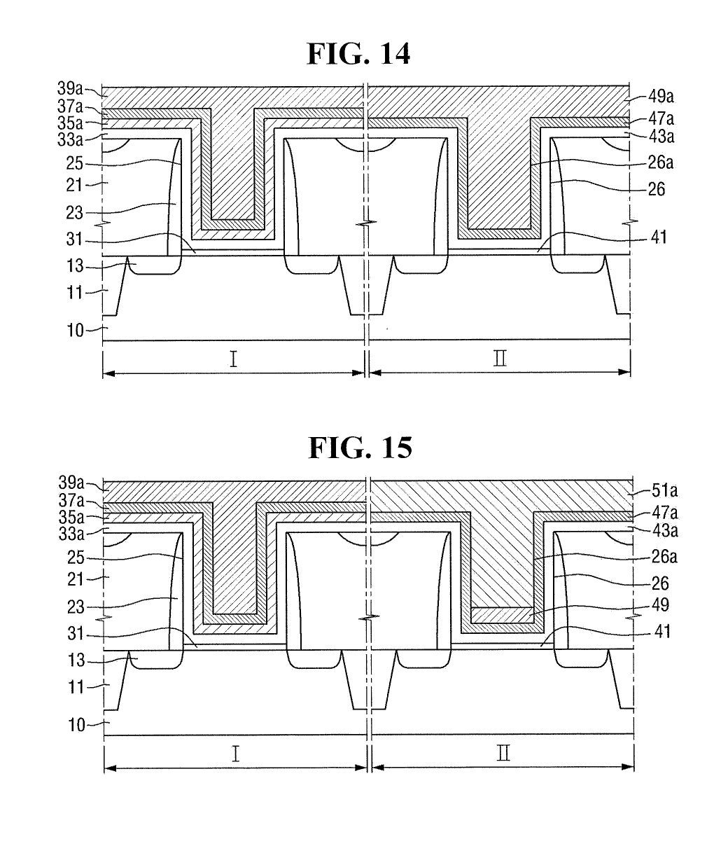

Referring to FIG. 14, a second conductivity type second work function control film 47a is formed on a second gate insulating film 43a of the second region II. The second conductivity type second work function control film 47a may be conformally formed along the sidewall and bottom surface of the second trench 26. The second conductivity type second work function control film 47a may form a trench 26a smaller than the second trench 26. According to the present example embodiment, the second conductivity type is different from the first conductivity type. The second conductivity type may be, for example, an N type.

Meanwhile, when the second conductivity type second work function control film 47a is formed, a second conductivity type first work function control film 37a may be additionally formed on the first conductivity type work function control film 35a of the first region I. The second conductivity type first work function control film 37a may be conformally formed along the sidewall and bottom surface of the first trench 25.

According to the present example embodiment, even if the second conductivity type first work function control film 37a is formed on the first conductivity type work function control film 35a, only the first conductivity type work function control film 35a affects a work function of a transistor formed on the first region I.

Next, first and second gate metals 39a and 49a are formed. The first and second gate metals 39a and 49a may fill the first and second trenches 25 and 26 and may include a first material. The first material may include, for example, Al or W, etc.

Referring to FIG. 15, the second gate metal 49a is partially removed, and the other portion of the trench 26a from which the second gate metal 49a is removed is filled with a carrier mobility improving film 51a. In order to partially remove the second gate metal 49a, an etch-back process may be performed. The second gate metal 49a is partially removed and may remain only on a lower portion of the trench 26a.

The carrier mobility improving film 51a may include a second material. A lattice constant of the second material may be smaller than that of the first material. Therefore, the second material may apply a smaller compressive stress to a channel region than the first material. For example, the second material may include, for example, TiN, etc.

Next, a top surface of the interlayer insulating film 21 may be exposed by a CMP process, thereby manufacturing the semiconductor device 1 shown in FIG. 1. According to the present example embodiment, the carrier mobility improving film 51 includes the first material. Thus, it may apply a smaller compressive stress to the channel region of the substrate 1 than the second gate metal 49. Therefore, the transistor formed on the first region I may apply a smaller compressive stress to the channel region than the transistor formed on the second region II.

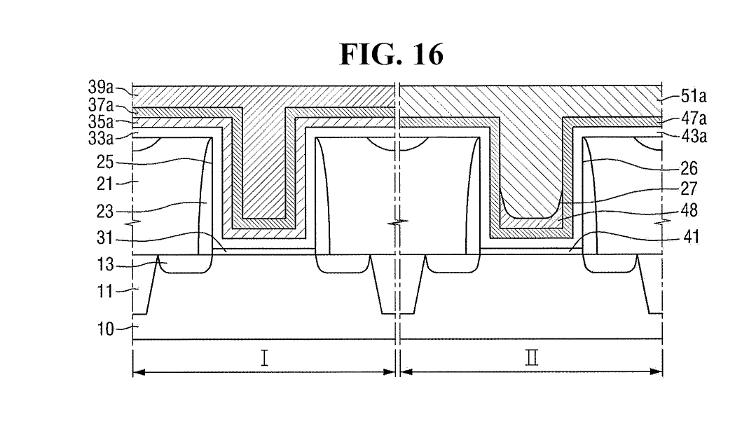

A method of fabricating the semiconductor device according to the second example embodiment will now be described with reference to FIGS. 2 and 16. In the following descriptions, previously-described details may not be repeated.

FIG. 16 illustrates a cross-sectional view of stages in a method of fabricating the semiconductor device according to the second example embodiment.

The method of fabricating the semiconductor device according to the second example embodiment is performed in substantially the same manner as the method of fabricating the semiconductor device according to the first embodiment, except for a configuration of a second gate metal 48 remaining after a second gate metal 49a is formed and the second gate metal 49a is then partially removed.

An etch-back process may be employed when the second gate metal 49a is partially removed. As the result of the etch-back process, the second gate metal 48 may have a recessed top surface, as shown in FIG. 16. Accordingly, the second gate metal 48 may include a third trench 27. Thus, the second gate metal 48 may remain on sidewalls and a lower portion of the trench 26a formed by the second conductivity type second work function control film 47a.

Next, a carrier mobility improving film 51a is formed on the second gate metal 48. The carrier mobility improving film 51a covers the second gate metal 48 and fills the second trench 26 while filling the third trench 27.

Next, top surfaces of the interlayer insulating film 21 are exposed by a CMP process, thereby manufacturing the semiconductor device 2 shown in FIG. 2.

A method of fabricating the semiconductor device according to the third example embodiment will now be described with reference to FIGS. 3 and 17 to 23. In the following descriptions, previously-described details may not be repeated.

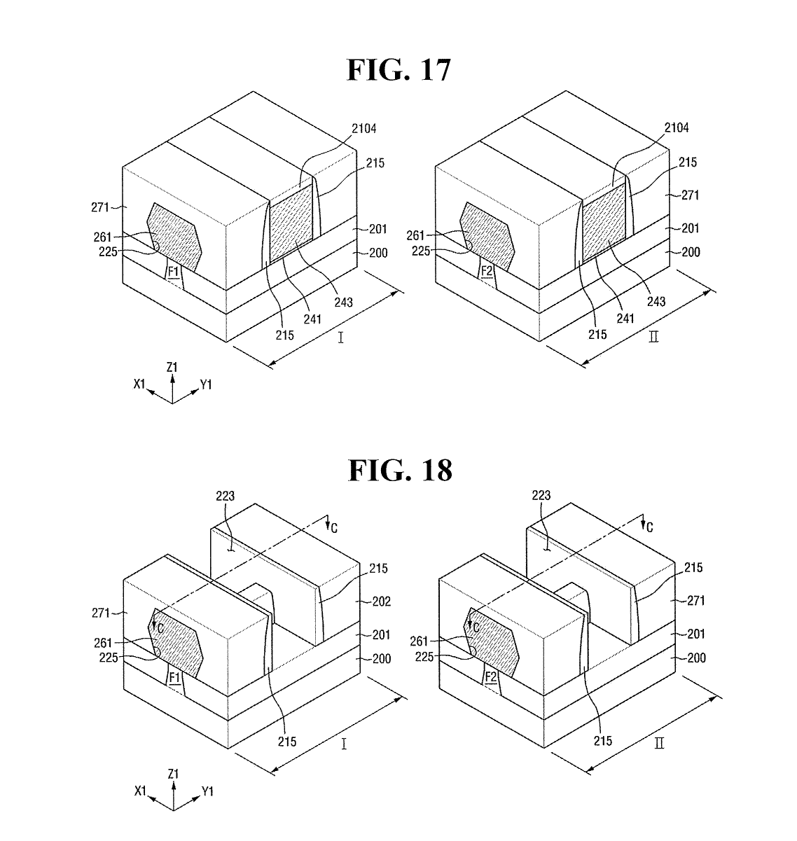

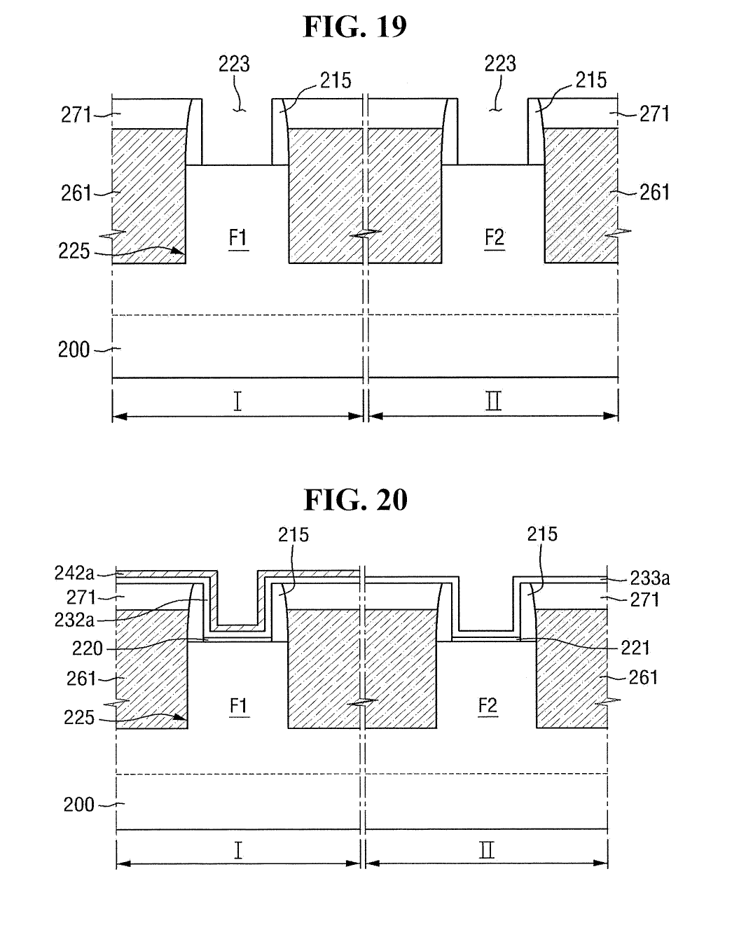

FIGS. 17 to 23 illustrate cross-sectional views illustrating intermediate process steps in a method of fabricating the semiconductor device according to the third example embodiment. Specifically, FIGS. 19 to 23 are cross-sectional views taken along the line C-C shown in FIG. 18.

Referring to FIG. 17, the elevated source/drain 261 is formed in the recess 225 formed on the first and second fins F1 and F2, and an interlayer insulating film 271 covering the elevated source/drain 261 is then formed. The first and second fins F1 and F2 are formed on the substrate 200. The substrate 200 may include a first region I and a second region II. The first fin F1 may be formed on the first region I and the second fin F2 may be formed on the second region II. For example, the first region I may be a PMOS region and the second region II may be an NMOS region.

Meanwhile, an impurity for adjusting a threshold voltage may be doped into the first and second fins F1 and F2. If the first region I is a PMOS region, the impurity may be phosphorus (P) or arsenic (As). If the second region II is an NMOS region, the impurity may be boron (B).

In FIG. 17, the first and second fins F1 and F2 extend in a second direction Y1. Thus, the first fin F1 may extend in a first direction X1 and the second fin F2 may extend in the second direction Y1. The isolation film 201 may be formed on the substrate 200 to partially cover the sidewalls of the first and second fins F1 and F2. The isolation film 201 may be formed of at least one of a silicon oxide film, a silicon nitride film, and a silicon oxynitride film.

Meanwhile, portions of the first and second fins F1 and F2 protruding above the isolation film 201 may be formed by an epitaxial process. For example, the portions of the first and second fins F1 and F2 may be formed by an epitaxial process using top surfaces of the first and second fins F1 and F2 exposed by the isolation film 201 without performing a recess process after forming the isolation film 201.

A dummy gate structure may extend in the first direction X1 to cross the first and second fins F1 and F2. The dummy gate structure may be formed by sequentially stacking a dummy gate insulating film 241, a dummy gate electrode 243, and a mask pattern 2104. For example, the dummy gate insulating film 241 may be formed of a silicon oxide film and the dummy gate electrode 243 may be formed of polysilicon. The spacer 215 is formed on sidewalls of the dummy gate structure. The spacer 215 may be, e.g., a silicon nitride film or a silicon oxynitride film.

The recess 225 may be formed by removing portions of the first and second fins F1 and F2 exposed at both sides of the dummy gate electrode 243.

The elevated source/drain 261 is formed in the recess 225 by, e.g., an epitaxial process. A material for forming the elevated source/drain 261 may vary according to whether the semiconductor device formed on the first and second regions I and II is an N type transistor or a P type transistor. The impurity may be in situ doped during the epitaxial process.

In FIG. 17, the elevated source/drain 261 may be shaped as a diamond, a pentagon, a hexagon, etc. The elevated source/drain 261 may have at least one of a circular shape and a rectangular shape.

The elevated source/drain 261 may be formed of, for example, at least one of an oxide film, a nitride film, and an oxynitride film.

Referring to FIG. 18, the interlayer insulating film 271 is planarized until a top surface of the dummy gate electrode 243 is exposed. As the result, the mask pattern 2104 is removed and the top surface of the dummy gate electrode 243 may be exposed.

Next, the dummy gate insulating film 241 and the dummy gate electrode 243 are removed. After the dummy gate insulating film 241 and the dummy gate electrode 243 are removed, a trench 223 exposing the isolation film 201 is formed, thereby exposing the first and second fins F 1 and F2, as shown in FIG. 19.

Referring to FIG. 20, first and second interface films 220 and 221 are formed on top surfaces of the first and second fins F1 and F2. Next, first and second gate insulating films 232a and 233a are formed in the trench 223. The first and second gate insulating films 232a and 233a may be substantially conformally formed along the sidewall and bottom surface of the trench 223.

Next, a first conductivity type work function control film 242a is formed on the first gate insulating film 232a. The first conductivity type work function control film 242a may be conformally formed along the sidewall and bottom surface of the trench 223.

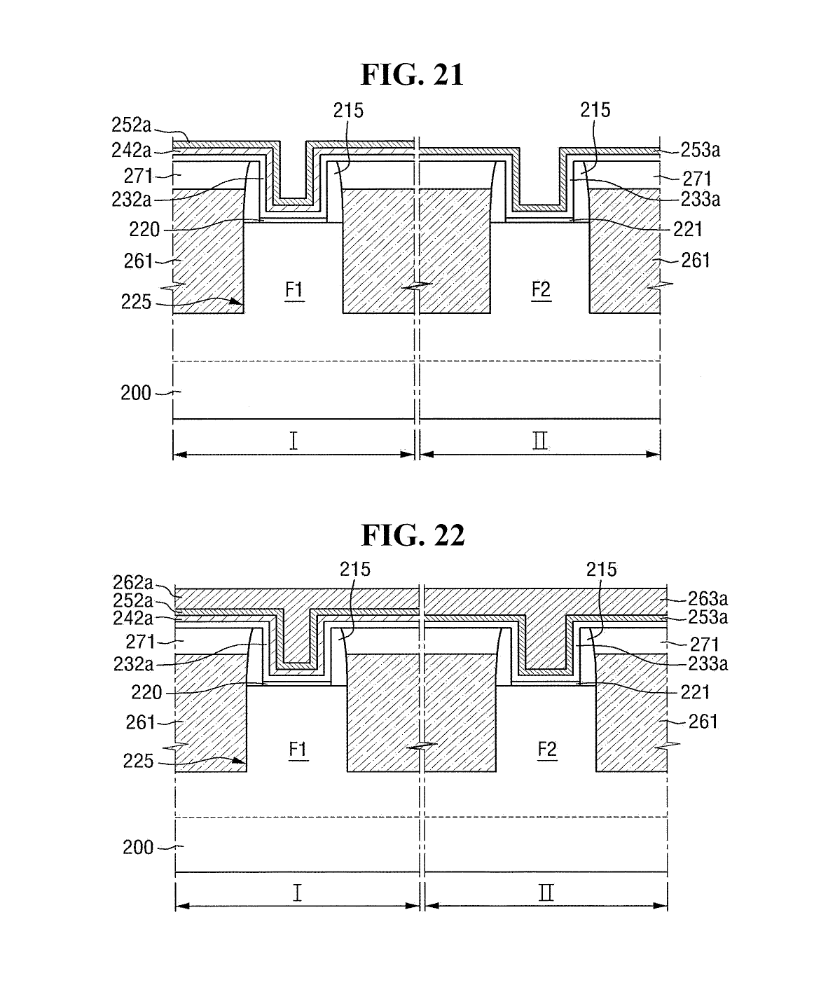

Referring to FIG. 21, a second conductivity type work function control film 253a is formed on the second gate insulating film 233a. The second conductivity type work function control film 253a may be conformally formed along the sidewall and bottom surface of the trench 223.

The first conductivity type may be a P type and the second conductivity type may be an N type, etc.

Meanwhile, when the second conductivity type work function control film 253a is formed on the second gate insulating film 233a, the second conductivity type work function control film 252a may also be formed on the first conductivity type work function control film 242a.

Referring to FIG. 22, the trench 223 may be filled with first and second gate metals 262a and 263a.

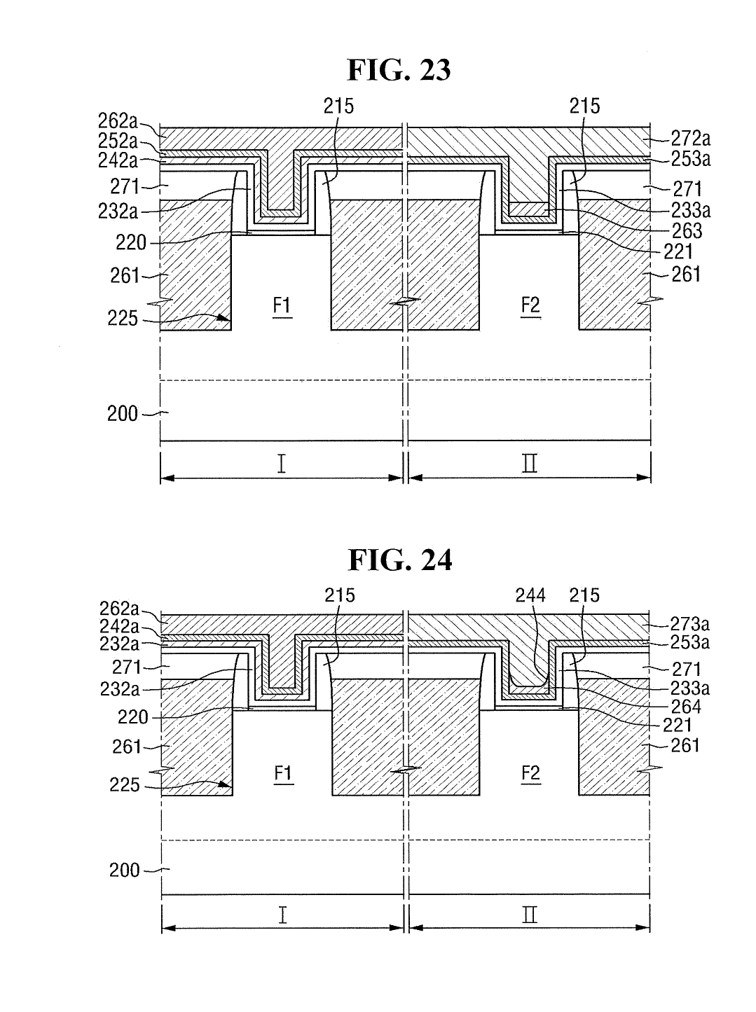

Referring to FIG. 23, the second gate metal 263a filling the trench 223 is partially removed, thereby forming a carrier mobility improving film 272a filling the remaining portion of the trench 223. The second gate metal 263a may exist only at a lower portion of the trench 223. The carrier mobility improving film 272a may include a second material, which is different from a first material included in the second gate metal 263a and has a smaller compressive stress than the first material.

Next, a planarization process is performed until a top surface of the interlayer insulating film 271 is exposed, thereby manufacturing the semiconductor device 3 shown in FIG. 3.

Next, a method of fabricating the semiconductor device 4 according to the first example embodiment will be described with reference to FIGS. 6 and 24. In the following descriptions, previously-described details may not be repeated.

FIG. 24 illustrates a cross-sectional view illustrating intermediate process steps in a method of fabricating the semiconductor device according to the fourth example embodiment.

The method of fabricating the semiconductor device according to the fourth example embodiment is performed in substantially the same manner as the method of fabricating the semiconductor device according to the third embodiment, except for a configuration of a second gate metal 264 remaining after a second gate metal 263a is formed and the second gate metal 263a is then partially removed.

An etch-back process may be employed when the second gate metal 263a is partially removed. As the result of the etch-back process, the second gate metal 264 may have a recessed top surface, as shown in FIG. 24. Accordingly, the second gate metal 264 may include a third trench 244. Thus, the second gate metal 264 may remain on sidewalls of the second work function control film 253.

Next, a carrier mobility improving film 273a is formed on the second gate metal 264. The carrier mobility improving film 273a covers the second gate metal 264 and fills the second trench 243 while filling the third trench 244.

Next, a CMP process is performed until a top surface of the interlayer insulating film 271 is exposed, thereby manufacturing the semiconductor device 4 shown in FIG. 6.

By way of summation and review, various studies are under way to increase capacitance between the gate and the channel and to improve operating characteristics of the MOS transistor.

A gate metal, e.g., Al, may have has a relatively large lattice constant. Thus, the gate metal may apply a pressure to a channel region. The pressure may improve performance of a P type transistor in a PMOS region in which the current flows through by holes. However, in an NMOS region in which the current flows through a carrier, the pressure may deteriorate performance of an N type transistor.

As described above, embodiments may provide a semiconductor device having improved operating characteristics by improving electron mobility. Embodiments may provide a method of fabricating a semiconductor device having improved operating characteristics by improving electron mobility. According to embodiments, a portion of a gate metal, e.g., Al, may be left in a trench and another portion of the trench may be filled with a carrier mobility improving film, e.g., TiN, to reduce the compressive stress applied to the NMOS channel region by the gate structure, which may improve the performance of the N type transistor. Further, the transistor may include a work function control film on a gate insulating film in the trench.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
an interlayer insulating film on a substrate, the interlayer insulating film including first and second trenches;
a gate insulating film in the first and second trenches;
a first conductivity type work function control film on the gate insulating film in the first trench;
a second conductivity type work function control film on the gate insulating film in the second trench;
a first gate metal on the first conductivity type work function control film, the first gate metal filling the first trench;
a second gate metal on the gate insulating film in the second trench; and
a carrier mobility improving film on the second conductivity type work function control film, the carrier mobility improving film filling the second trench.

2. The semiconductor device as claimed in claim 1, wherein the second gate metal includes a third trench formed in the second trench.

3. The semiconductor device as claimed in claim 2, wherein a top surface of the second gate metal is recessed.

4. The semiconductor device as claimed in claim 1, further comprising fins on the substrate and under the gate insulating film.

5. The semiconductor device as claimed in claim 1, wherein the first conductivity type work function control film and the second conductivity type work function control film are different from each other.

6. The semiconductor device as claimed in claim 5, wherein the first conductivity type work function control film is a P type and the second conductivity type work function control film is an N type.

7. The semiconductor device as claimed in claim 1, wherein, in the second trench, a volume of the second gate metal is smaller than that of the carrier mobility improving film.

8. The semiconductor device as claimed in claim 1, wherein the first and second gate metals include a first material, and the carrier mobility improving film includes a second material different from the first material.

9. The semiconductor device as claimed in claim 8, wherein the second material includes TiN.

10. The semiconductor device as claimed in claim 8, wherein a lattice constant of the second material is smaller than that of the first material.

11. A semiconductor device, comprising:
a substrate including an NMOS region;
a gate insulating film on the NMOS region;
an N type work function control film on the gate insulating film;
a gate metal on the N type work function control film and including a first material; and
a carrier mobility improving film on the gate metal and including a second material, a lattice constant of the second material being smaller than that of the first material.

12. The semiconductor device as claimed in claim 11, wherein the N type work function control film includes a first trench, the gate metal is formed at a lower portion of the trench, and the carrier mobility improving film is formed to fill the trench.

13. The semiconductor device as claimed in claim 12, wherein a volume of the gate metal is smaller than that of the carrier mobility improving film in the trench.

14. The semiconductor device as claimed in claim 12, wherein the gate metal includes a second trench.

15. A semiconductor device, comprising:
a substrate including a first region and a second region;
a P-type transistor in the first region, the P-type transistor having a first channel region and having a first gate structure disposed on the first channel region, the first gate structure including a first gate metal in a first trench that overlaps the first channel region, the first gate structure including a first material layer in the first trench under the first gate metal, the first material layer being interposed between a bottom of the first trench and the first gate metal over the first channel region; and
an N-type transistor in the second region, the N-type transistor having a second channel region and having a second gate structure disposed on the second channel region, the second gate structure including a second gate metal in a second trench that overlaps the second channel region, the second gate structure including a titanium nitride layer in the second trench on the second gate metal, the second gate metal being interposed between a bottom of the second trench and the titanium nitride layer over the second channel region, wherein the second gate structure does not include the first material in the second trench.

16. The semiconductor device as claimed in claim 15, wherein the first gate metal is tungsten or aluminum, and the second gate metal is tungsten or aluminum.

17. The semiconductor device as claimed in claim 16, wherein, in the second trench, the second gate metal contacts the titanium nitride layer.

18. The semiconductor device as claimed in claim 16, wherein the second gate structure includes a second material layer interposed between a bottom of the second trench and the titanium nitride layer over the second channel region, the second material layer being formed from a second material selected from the group of TiAl, TiAlN, TaC, TiC, and HfSi.

19. The semiconductor device as claimed in claim 18, wherein:
the P-type transistor has a first fin extending from the substrate in the first channel region, the first gate structure being disposed along sidewalls and a top of the first fin, the first trench being at a top of the first fin, and
the N-type transistor has a second fin extending from the substrate in the second channel region, second gate structure being disposed along sidewalls and a top of the second fin, the second trench being at a top of the second fin.

20. The semiconductor device as claimed in claim 18, wherein the first material layer IS formed from a first material selected from the group of Mo, Pd, Ru, Pt, TiN, WN, TaN, Ir, TaC, RuN, and MoN.
